(19) United States
(12) Patent Application Publication
(10) Pub. No.: US 2003/0003712 A1
(43) Pub. Date: Jan. 2, 2003

(54) Methods for fabricating a semiconductor device

(75) Inventors: Pan Ki Kwon, Kyoungki-do (KR); Sang Ick Lee, Kyoungki-do (KR); Chul Woo Nam, Kyoungki-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Kyoungki-do (KR)

(21) Appl. No.: 10/184,783

(22) Filed: Jun. 27, 2002

(30) Foreign Application Priority Data
Jun. 30, 2001 (KR) 2001-39039

(51) Int. Cl. H01L 21/4763; H01L 21/3205

(52) U.S. Cl. 438/630; 438/633; 438/634; 438/586

(57) ABSTRACT

The present invention discloses methods for fabricating a semiconductor device. A gate electrode having a hard mask layer at its upper portion is formed, and an interlayer insulating film is formed over the resultant structure. A landing plug contact hole is formed by etching the interlayer insulating film, and a conductive layer is formed over the resultant structure, filling up the landing plug contact hole. A first CMP process is performed to expose the hard mask layer, and a second CMP process is preformed to planarize the hard mask layer, the interlayer insulating film and the landing plug conductive layer. The CMP processes of the present invention reduce or prevent dishing of the mask insulating film or contact plug, to reduce or prevent the likelihood of a bridge forming between adjacent conductive plugs. As a result, the semiconductor device has improved properties and/or improved yield.

### BACKGROUND OF THE INVENTION

1. Field of the Invention

The present invention relates to methods for fabricating a semiconductor device, and in particular to a technology for preventing dishing of a dielectric film, such as a silicon oxide film, which is a peripheral interlayer insulating film in a chemical mechanical polishing (CMP) process of a contact plug conductive layer.

2. Description of the Background Art

A conventional CMP process isolates a plug by using a basic slurry. A nitride film is typically used as a hard mask layer of a word line, and an oxide film is typically used as a planarization and gap fill material. In a polishing process of a plug material, the plug material and the oxide film are dished more than the nitride film due to differences in an etching selectivity ratio of the three materials. It is thus necessary to deposit another oxide film.

When CMP process residues fall into the dished region of the plug material and the oxide film, the residues may not be removed in a succeeding cleaning process. As a result, a bridge may be formed between a bit line contact plug and a storage electrode contact plug. Such a bridge undesirably reduces device yield.

FIGS. 1A through 1C are diagrams illustrating sequential steps of a conventional method for fabricating a semiconductor device.

Referring to FIG. 1A, a word line 13 is formed on a semiconductor substrate 11. Here, a nitride film 15 is formed at the upper portion of the word line 13. An interlayer insulating film 17 is formed over the resultant structure. Thereafter, a landing plug contact hole 19 for a bit line and a storage electrode is formed by etching the interlayer insulating film 17 using a landing plug mask (not shown).

As shown in FIG. 1B, a landing plug conductive layer 21 is formed over the resultant structure. Landing plug conductive layer 21, which in one embodiment is a poly, fills up the landing plug contact hole 19. As illustrated in FIG. 1C, a landing plug poly is formed by etching landing plug conductive layer 21 according to a conventional chemical mechanical polishing (CMP) process.

At this time, interlayer insulating film 17 and landing plug conductive layer 21 are over-etched due to differences in an etching selectivity ratio of landing plug conductive layer 21, the oxide film used as interlayer insulating film 21 and nitride film 15. As a result, it can be difficult to perform subsequent processes.

FIG. 1D is a SEM photograph showing a Pinocchio defect, which is a bridge between conductive layers. Here, the contact plug conductive layer is dished due to over-etching in the CMP process, and/or the BPSG interlayer insulating film is dished due to over-etching in the CMP process, as compared to etching of the nitride film. Accordingly, a bit line contact plug and a storage electrode contact plug are shorted out in a subsequent process due to residues generated in the CMP process of the landing plug poly (see FIG. 3A).

As described above, the conventional method for fabricating the semiconductor device has disadvantages in that a property and yield of the device are deteriorated due to the dishing effects.

### BRIEF SUMMARY OF THE INVENTION

Accordingly, the present invention provides methods for fabricating a semiconductor device which can improve a property and reliability of the semiconductor device. In one embodiment, the fabrication method includes performing a first CMP process exposing a nitride film, which is a hard mask of a word line, and performing a second CMP process using a slurry having a high etching selectivity ratio difference.

One such method for fabricating a semiconductor device according to the present invention includes forming a gate electrode having a hard mask layer at its upper portion, forming an interlayer insulating film over the resultant structure, and forming a landing plug contact hole by etching the interlayer insulating film. The method includes forming a landing plug conductive layer, which in one embodiment is a poly layer, over the resultant structure to fill up the landing plug contact hole. A first CMP process is performed to expose the hard mask layer by using a slurry containing SiO₂. A second CMP process is performed using a slurry containing CeO₂ to planarize the hard mask layer, the interlayer insulating film and the landing plug conductive layer.

In one aspect of the present invention, the hard mark layer comprises a nitride film having a thickness less than about 500 Å. In another aspect, the second CMP process uses an etching select ratio of the interlayer insulating film to the hard mask layer that is at least 5:1. In one aspect, the etching selectivity ratio of the interlayer insulating film to the landing plug conductive layer is at least 2:1. In still another aspect, an etching selectivity ratio of the landing plug conductive layer to the hard mask layer is at least 2:1. In one embodiment, the method further includes forming a spacer in the landing plug contact hole.

### BRIEF DESCRIPTION OF THE DRAWINGS

The present invention will become better understood with reference to the accompanying drawings which are provided only for illustration and thus are not intended to limit the scope of the present invention, wherein:

FIGS. 1A through 1C are diagrams illustrating sequential steps of a conventional method for fabricating a semiconductor device;

FIG. 1D is an SEM photograph showing defects of the conventional semiconductor device;

FIGS. 2A through 2C are diagrams illustrating sequential steps of a method for fabricating a semiconductor device in accordance with the present invention;

FIG. 3A is an SEM photograph showing a bridge defect of the conventional semiconductor substrate; and

FIG. 3B is an SEM photograph showing the semiconductor device in accordance with the present invention.

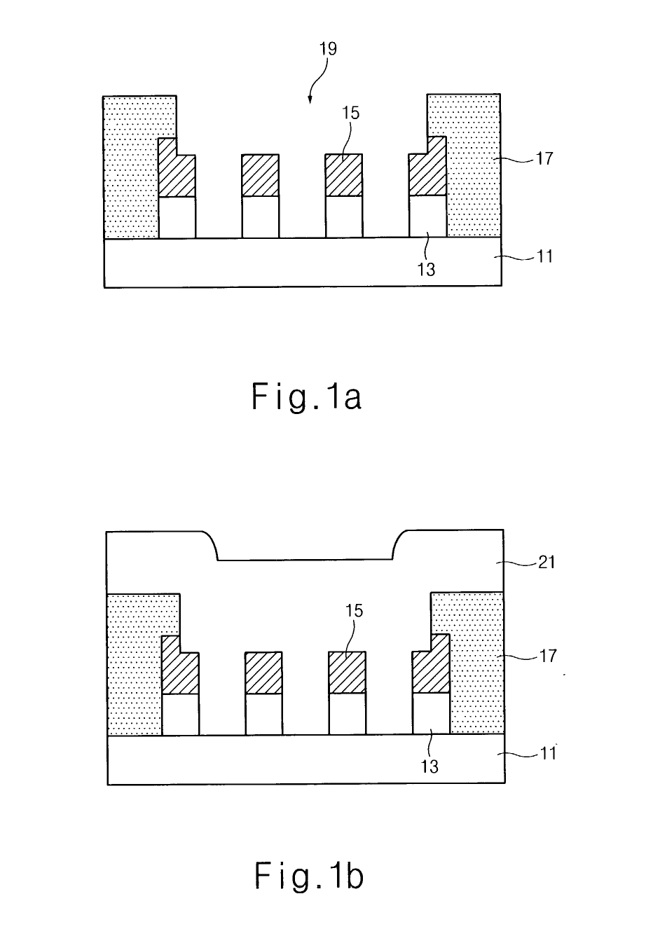

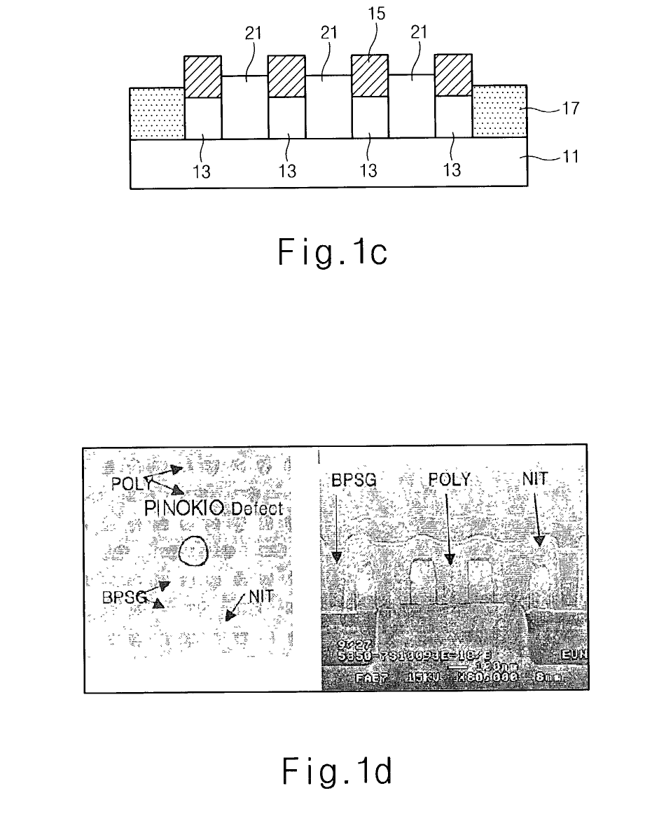

### DETAILED DESCRIPTION OF THE INVENTION

A method for fabricating a semiconductor device in accordance with an embodiment of the present invention will now be described in detail with reference to the accompanying drawings.

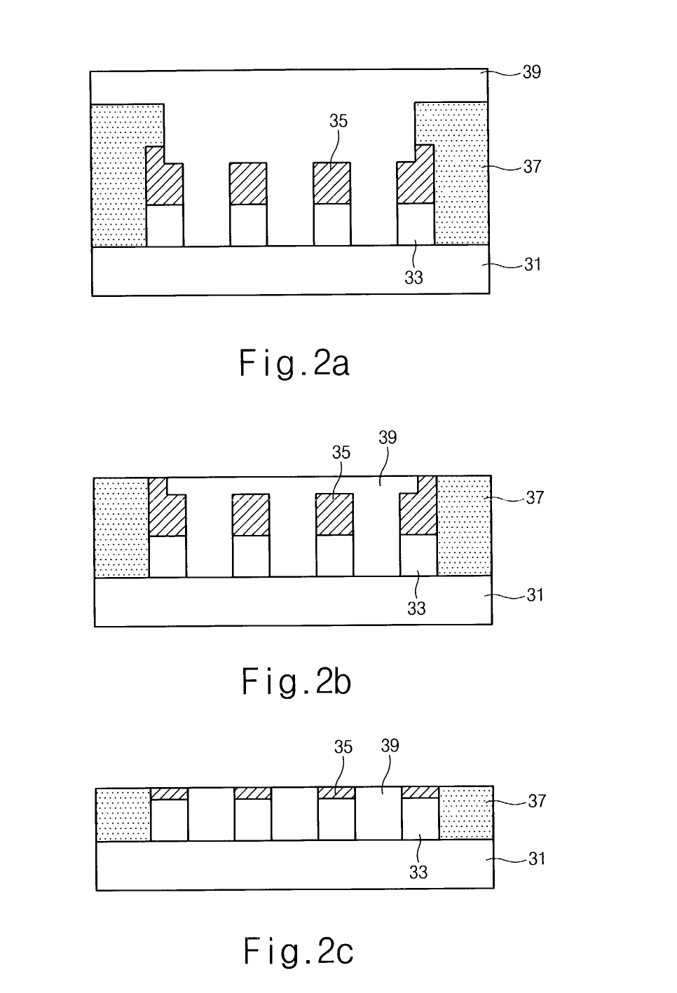

FIGS. 2A through 2C illustrate sequential steps of a method for fabricating the semiconductor device in accordance with an embodiment of the present invention.

Referring to FIG. 2A, a word line 33 is formed on a semiconductor substrate 31. A nitride film 35 is formed on an upper portion of word line 33. An interlayer insulating film 37 is formed over the resultant structure. In one embodiment, interlayer insulating film 37 comprises an oxide film.

Thereafter, a landing plug contact hole (not shown) for a bit line and a storage electrode is formed by etching interlayer insulating film 37 according to a photolithography process using a landing plug mask (not shown). A landing plug conductive layer 39 is formed over the resultant structure, substantially filling or completely filling up the landing plug contact hole. In alternative embodiments, conductive layer 39 comprises a polysilicon or poly, one or more silicon films, or the like. In another embodiment conductive layer 39 comprises a metal. In another embodiment, an insulating film spacer is formed in the contact hole prior to forming conductive layer 39.

Referring to FIG. 2B, a first CMP process is performed on landing plug conductive layer 39 and interlayer insulating film 37. In a particular embodiment, the first CMP process uses a slurry containing silicon dioxide (SiO₂). In one embodiment, the first CMP process is performed a sufficient amount to expose nitride film 35.

Referring to FIG. 2C, a second CMP process is performed to planarize landing plug conductive layer 39, interlayer insulating film 37, and nitride film 35. In a particular embodiment, the second CMP process uses a slurry containing cerium dioxide (CeO₂).

In one embodiment, the slurry used in the second CMP process has an etching selectivity ratio for the oxide film as compared to the nitride film that is about 5:1, and in another embodiment is greater than 5:1. In one embodiment, the slurry used in the second CMP process has an etching selectivity ratio for the oxide film compared to the conductive layer that is about 2:1, and in another embodiment is greater than 2:1. In still another embodiment, the slurry used in the second CMP process has an etching selectivity ratio that is about 2:1, and in another embodiment is greater than 2:1, for the etch selectivity of the conductive layer compared to the etch selectivity of the nitride film. It will be appreciated by those skilled in the art that a single slurry used in the second CMP process may have one, or more than one, or all of the above noted etching selectivity ratios.

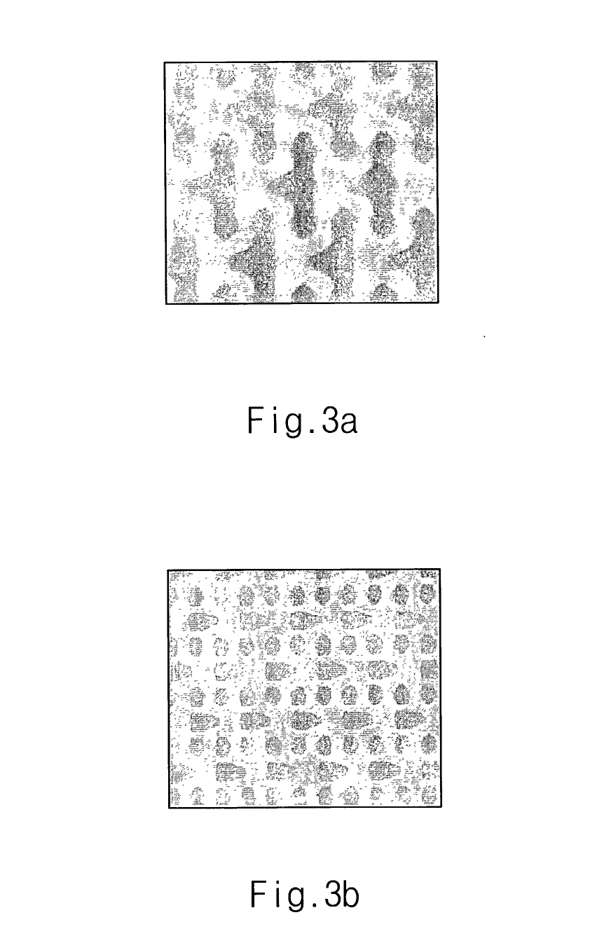

The upper portion of the resulting structure is planarized according to the second CMP process, which effectively removes a bridge which may be generated between the conductive layers in the contact process, known as a Pinocchio defect (see FIG. 3B).

Defects generated as a result of the exposed layers having different polishing properties are removed or reduced using methods of the present invention. The two-step CMP process using the slurry having high etching selectivity ratio differences results in improved device properties and improved reliability of the device.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims.

What is claimed is:

1. A method for fabricating a semiconductor device, said method comprising:
forming a gate electrode having a hard mask layer at an upper portion of the gate electrode;
forming an interlayer insulating film over the gate electrode and over an adjacent region;
forming a landing plug contact hole by etching the interlayer insulating film in the adjacent region;
forming a conductive layer over the interlayer insulating film and over the landing plug contact hole, the conductive layer at least substantially filling the landing plug contact hole for forming a conductive landing plug;
performing a first CMP process to expose the hard mask layer, the first CMP process comprising using a slurry containing silicon dioxide (SiO₂); and
performing a second CMP process to planarize the hard mask layer, the interlayer insulating film and the conductive layer, the second CMP process comprising using a slurry containing cerium dioxide (CeO₂).

2. The method according to claim 1, wherein the hard mark layer comprises a nitride film having a thickness that is less than about 500 Å.

3. The method according to claim 1, wherein an etching selectivity ratio of the interlayer insulating film compared to the hard mask layer for the second CMP process is greater than 5:1.

4. The method according to claim 1, wherein an etching selectivity ratio of the interlayer insulating film compared to the conductive layer for the second CMP process is greater than 2:1.

5. The method according to claim 1, wherein an etching selectivity ratio of the conductive layer compared to the hard mask layer for the second CMP process is greater than 2:1.

6. The method according to claim 1, further comprising forming a spacer in the landing plug contact hole.

7. The method according to claim 6, wherein the spacer comprises a dielectric.

8. The method according to claim 1, wherein the conductive landing plug comprises a poly.
